(19) United States
(12) Patent Application Publication
(10) Pub. No.: US 2025/0143018 A1
(43) Pub. Date: May 1, 2025

(54) LIGHT-EMITTING DIODE AND LIGHT-EMITTING DEVICE

(71) Applicant: XIAMEN SAN'AN OPTOELECTRONICS CO., LTD., Xiamen (CN)

(72) Inventors: QING WANG, Xiamen (CN); LING-YUAN HONG, Xiamen (CN); MINYOU HE, Xiamen (CN); JIANGBIN ZENG, Xiamen (CN); CHAO LU, Xiamen (CN); GUANGYAO WU, Xiamen (CN); CHUNG-YING CHANG, Xiamen (CN)

(21) Appl. No.: 18/919,343

(22) Filed: Oct. 17, 2024

(30) Foreign Application Priority Data
Oct. 31, 2023 (CN) 2023114394188

(51) Int. Cl. H01L 33/10

(52) U.S. Cl. CPC H10H 20/814

(57) ABSTRACT

A light-emitting diode and a light-emitting device are provided, the light-emitting diode includes a substrate, an epitaxial structure and a Bragg reflector. The Bragg reflector includes first film stacks and second film stacks repeatedly and alternately stacked. The first film stack includes at least one pair layer consisting of a first material layer and a second material layer, an optical thickness of the first material layer is greater than that of the second material layer in each pair layer. The second film stack includes multiple pair layers consisting of a first material layer and a second material layer; and the second film stack is formed by repeatedly and alternately stacking a pair layer with optical thickness of the first material layer greater than that of the second material layer and a pair layer with optical thickness of the first material layer smaller than that of the second material layer.

### CROSS-REFERENCE TO RELATED APPLICATION

This application claims priority to Chinese Patent Application No. 202311435014.1, filed on Oct. 31, 2023, which is herein incorporated by reference in its entirety.

### TECHNICAL FIELD

The disclosure relates to the field of semiconductor manufacturing technologies, and more particularly to a light-emitting diode and a light-emitting device.

### BACKGROUND

Light-emitting diode (LED) is a semiconductor light-emitting element, which is usually made of semiconductors such as gallium nitride (GaN), gallium arsenide (GaAs), gallium phosphide (GaP), gallium arsenide phosphide (GaAsP). A core of the LED is a PN junction with light-emitting properties. LED has the advantages of high light-emitting intensity, high efficiency, small size, and long service life, and is considered to be one of the most promising light sources currently. LED has been widely used in lighting, monitoring and command, high-definition studio, high-end cinema, office display, conference interaction, virtual reality and other fields.

A distributed Bragg reflector mirror (DBR) is an important element of LED. The quality of DBR will directly affect the brightness of LED. Therefore, how to continuously optimize DBR to improve the brightness of LED is an urgent technical problem.

### SUMMARY

The disclosure provides a light-emitting diode, which solves at least one technical problem in the related art to effectively improve light-emitting effect. The disclosure provides a light-emitting diode, including: a substrate, an epitaxial structure and a Bragg reflector. The substrate defines a first surface and a second surface that are oppositely disposed. The epitaxial structure is disposed on the first surface, and includes an active layer. The Bragg reflector is disposed on the second surface.

The Bragg reflector includes first film stacks and second film stacks that are repeatedly and alternately stacked. Each of the first film stacks and the second film stacks includes a first material layer with a first refractivity and a second material layer with a second refractivity, the first material layer and the second material layer are repeatedly and alternately stacked, and the first refractivity is lower than the second refractivity.

Each of the first film stacks includes at least one pair layer, each pair layer consists of the first material layer and the second material layer, and an optical thickness of the first material layer is greater than that of the second material layer in each pair layer.

Each of the second film stacks includes multiple pair layers, each pair layer consists of the first material layer and the second material layer, and each of the second film stacks is formed by repeatedly and alternately stacking a pair layer with the optical thickness of the first material layer greater than that of the second material layer and a pair layer with the optical thickness of the first material layer smaller than that of the second material layer.

The disclosure further provides a light-emitting device, including the light-emitting diode provided in the above embodiment.

Through setting the Bragg reflector with respect to the first film stacks and the second film stacks, the light-emitting diode provided by the embodiment of the disclosure can improve a refractivity near a Brewster angle inside the chip and greatly improve a reflectivity of the entire structure of the Bragg reflector in the light-emitting diode, the light-emitting diode not only has a high reflectivity for light coming from the active layer in a direction proximate to a right angle (i.e., light with a small incident angle), but also exhibits a good reflectivity for light in a direction deviating from the right angle (i.e., light with a large incident angle), which effectively improves the overall brightness of the light-emitting diode.

### BRIEF DESCRIPTION OF DRAWINGS

FIG. 1 illustrates a sectional diagram of a light-emitting diode according to an embodiment of the disclosure.

FIG. 2 illustrates a schematic diagram of a stacking structure of a Bragg reflector of the light-emitting diode according to an embodiment of the disclosure.

FIG. 3 illustrates a curve diagram of refractivity of the Bragg reflectors with different stacking sequences according to an embodiment of the disclosure.

FIG. 4 illustrates a schematic diagram of a stacking sequence of the Bragg reflector according to an embodiment of the disclosure.

### LIST OF REFERENCE NUMBER

10—epitaxial structure; 11—first semiconductor layer; 12—active layer; 13—second semiconductor layer; 20—Bragg reflector; 21—first material layer; 22—second material layer; 30—transparent substrate; 40—first electrode; 50—second electrode; 60—insulation layer; 70—transparent conductive layer; 80—current blocking layer.

### DETAILED DESCRIPTION OF EMBODIMENTS

An embodiment of the disclosure provides a light-emitting diode, including a substrate 30, an epitaxial structure 10 and a Bragg reflector 20. The substrate 30 defines a first surface and a second surface that are oppositely disposed. The first surface is an upper surface of the substrate 30, and the second surface is a lower surface of the substrate 30. The epitaxial structure 10 is disposed on the first surface of the substrate 30, and includes an active layer 12. The Bragg reflector 20 is disposed on the second surface of the substrate 30.

The Bragg reflector 20 includes first film stacks and second film stacks that are repeatedly and alternately stacked. Each of the first film stacks and the second film stacks includes a first material layer 21 with a first refractivity and a second material layer 22 with a second refractivity, the first material layer 21 and the second material layer 22 are repeatedly and alternately stacked, and the first refractivity is lower than the second refractivity.

Each of the first film stacks includes at least one pair layer, each pair layer consists of the first material layer 21 and the second material layer 22, and an optical thickness of the first material layer 21 is greater than that of the second material layer 22 in each pair layer.

Each of the second film stacks includes multiple pair layers, each pair layer consists of the first material layer 21 and the second material layer 22, and each of the second film stacks is formed by repeatedly and alternately stacking a pair layer with the optical thickness of the first material layer 21 greater than that of the second material layer 22 and a pair layer with the optical thickness of the first material layer 21 smaller than that of the second material layer 22.

Through setting the Bragg reflector 20 with respect to the first film stacks and the second film stacks, the embodiment can improve a refractivity near a Brewster angle inside the chip and greatly improve a reflectivity of the entire structure of the Bragg reflector 20 in the light-emitting diode, the light-emitting diode provided in the embodiment not only has a high reflectivity for light coming from the active layer 12 in a direction proximate to a right angle (i.e., light with a small incident angle), but also exhibits a good reflectivity for light in a direction deviating from the right angle (i.e., light with a large incident angle), which effectively improves the overall brightness of the light-emitting diode.

In an embodiment, in a same Bragg reflector 20, a number of layers contained in each of the first film stacks is same or different, and a number of layers contained in each of the second film stacks is same or different, which can be specifically selected according to actual needs, and is not limited here.

In an embodiment, the total number of layers contained in the first film stacks is greater than the total number of layers contained in the second film stacks.

In an embodiment, the number of layers contained in the first film stack is greater than or equal to 2, and the number of layers contained in the second film stack is greater than or equal to 4, to further improve a refractivity of the light-emitting diode.

In an embodiment, in the same Bragg reflector 20, a number of the first film stacks and a number of the second film stacks are same or different.

In an embodiment, in the Bragg reflector 20, a film stack closest to the epitaxial structure 10 is the first film stack, to preferentially improve an internal reflectivity of a wide-angle light-emitting diode.

In an embodiment, a material of the first material layer 21 is silicon oxide, and a material of the second material layer 22 is titanium oxide.

In an embodiment, a sum of the number of the pair layers of the first film stacks and the number of the pair layers of the second film stacks is in a range of 15 pairs to 30 pairs, to thereby more effectively improve the reflectivity near the Brewster angle.

In an embodiment, in the Bragg reflector 20, a material layer closest to the epitaxial structure 10 is defined as a first layer, and the first layer is made of a low refractivity material. An optical thickness of the first layer is greater than that of other material layers in the Bragg reflector 20, which not only protects the Bragg reflector 20, but also improves a total reflection effect.

In an embodiment, the first layer is the first material layer 21, to thereby ensure an adhesive effect of the first layer.

In an embodiment, the optical thickness of the first layer is in a range of 588 nanometers (nm) to 1470 nm.

In an embodiment, an optical thickness of each first material layer is λ₁/4, and λ₁>350 nm, to thereby ensure stability of the coating of the first material layer 21.

In an embodiment, an optical thickness of each second material layer is λ₂/4, and 350 nm≤λ₂≤880 nm, to thereby ensure stability of the coating of the second material layer 22, while also allowing the optical thickness to cover a visible light region.

In an embodiment, a thickness of the Bragg reflector 20 is in a range of 3 microns (μm) to 6 μm.

In an embodiment, a light-emitting wavelength of the light-emitting diode is in a range of 420 nm to 480 nm.

In an embodiment, a transparent substrate 30 is disposed between the epitaxial structure 10 and the Bragg reflector 20, and the transparent substrate 30 includes but is not limited to a sapphire flat bottomed substrate or a sapphire graphic substrate. The transparent substrate 30 defines a first surface and a second surface that are oppositely disposed. Specifically, the first surface is an upper surface of the transparent substrate 30, and the second surface is a lower surface of the transparent substrate 30, so that the light source passes through the transparent substrate 30 and is reflected from a light-emitting surface of the light-emitting diode through the Bragg reflector 20.

In an embodiment, the epitaxial structure 10 further includes a first semiconductor layer 11 and a second semiconductor layer 13 stacked on two sides of the active layer 12, respectively; and the first semiconductor layer 11 is located proximate to the transparent substrate 30.

In an embodiment, the light-emitting diode further includes a first electrode 40, a second electrode 50 and an insulation layer 60. The first electrode 40 is disposed on the first semiconductor layer 11, and electrically connected to the first semiconductor layer 11. The second electrode 50 is disposed on the second semiconductor layer 13, and electrically connected to the second semiconductor layer 13. The insulation layer 60 covers at least part of the epitaxial structure 10.

In an embodiment, the light-emitting diode further includes a transparent conductive layer 70 and a current blocking layer 80. The transparent conductive layer 70 is disposed between the second electrode 50 and the epitaxial structure 10. The current blocking layer 80 is disposed in the transparent conductive layer 70. Through the above settings, structural reliability can be further ensured while the brightness of the light-emitting diode is improved.

The disclosure further provides a light-emitting device, and the light-emitting device adopts the light-emitting diode as described in the above embodiments, which can effectively improve the performance of the light-emitting device.

Drawings in the embodiments of the disclosure will be combined below to clearly and completely describe technical solutions of the disclosure through multiple embodiments.

Please refer to FIG. 1, FIG. 1 illustrates a sectional diagram of a light-emitting diode provided by an embodiment of the disclosure. In order to achieve at least one of the advantages or other advantages, the embodiment of the disclosure provides a light-emitting diode. As shown in FIG. 1, the light-emitting diode includes a substrate 30, an epitaxial structure 10 and a Bragg reflector 20.

The substrate 30 can be a transparent substrate or a semitransparent substrate. For example, the substrate 30 can be a sapphire flat bottomed substrate or a sapphire graphic substrate. In some embodiments, the substrate 30 can be a combined patterned substrate. In other embodiments, the substrate 30 can be a chip which is thinned or removed to form a thin film. The substrate 30 defines a first surface and a second surface opposite to the first surface, the first surface is an upper surface of the substrate 30, and the second surface is a lower surface of the substrate 30.

The epitaxial structure 10 is disposed on the first surface of the substrate 30, and the transparent substrate or the semitransparent substrate can allow the light emitted by an active layer 12 to pass through the substrate 30 to arrive the Bragg reflector 20 disposed on a side of the substrate 30. In an embodiment, the epitaxial structure 10 includes a first semiconductor layer 11, the active layer 12 and a second semiconductor layer 13 sequentially stacked in that order. Specifically, the first semiconductor layer 11 is disposed on substrate 30. The first semiconductor layer 11 is a layer grown on the substrate 30, and can be a layer doped with n-type impurities, for example, a gallium nitride semiconductor layer doped with silicon (Si). In some embodiments, a buffer layer can be disposed between the first semiconductor layer 11 and the substrate 30. In other embodiments, the first semiconductor layer 11 can be connected to the substrate 30 through an adhesive layer.

The active layer 12 can be a quantum well (QW) structure. In some embodiments, the active layer 12 can be also a multiple quantum well (MQW) structure, and the MQW structure includes multiple QW layers and multiple quantum barrier layers repeatedly and alternately arranged. In addition, the composition and thickness of the well layers within the active layer 12 determine the wavelength of the generated light. Especially, the active layer 12 generating different colors of light such as ultraviolet, blue, green, and yellow can be provided through adjusting the composition of the well layers. In the embodiment, the light-emitting wavelength of the light-emitting diode is in a range of 420 nm to 480 nm.

The second semiconductor layer 13 can be a layer doped with p-type impurities, for example, a gallium nitride semiconductor layer doped with magnesium (Mg). The first semiconductor layer 11 and the second semiconductor layer 13 may each have a single-layer structure, but the disclosure is not limited to this, the first semiconductor layer 11 and the second semiconductor layer 13 may also have multiple layers, and may also include a superlattice layer. In addition, in other embodiments, when the first semiconductor layer 11 is the layer doped with p-type impurities, the second semiconductor layer 13 may be the layer doped with n-type impurities, that is, the first semiconductor layer 11 is a p-type semiconductor layer and the second semiconductor layer 13 is an n-type semiconductor layer.

Certainly, the epitaxial structure 10 can also include other layer materials, such as a window layer or an ohmic contact layer, and is disposed as different multiple layers according to different doping concentration or component content.

In an embodiment, the Bragg reflector 20 is disposed on the second surface of the substrate 30, and the Bragg reflector 20 includes first film stacks and second film stacks that are repeatedly and alternately stacked. A number of the first film stacks and a number of the second film stacks are greater than or equal to 1, specific numbers of the first film stacks and the second film stacks can be designed according to actual needs, and are not limited here.

In an embodiment, a thickness of the Bragg reflector 20 is in a range of 3 μm to 6 μm. In a same Bragg reflector 20, the number of the first film stacks and the number of the second film stacks can be same or different. That is, the number of the first film stacks can be 3, and the number of the second film stacks can also be 3, or the number of the first film stacks can be 3, and the number of the second film stacks can be 2, ensuring that the difference between the number of the first film stacks and the number of the second film stacks is 1.

Specifically, each of the first film stacks and the second film stacks includes a first material layer 21 with a first refractivity and a second material layer 22 with a second refractivity, the first material layer 21 and the second material layer 22 are repeatedly and alternately stacked, and the first refractivity is lower than the second refractivity. The terms “high refractivity” and “low refractivity” are used to indicate a difference between the refractivity of the first material layer 21 and the refractivity of the second material layer 22. That is, the first material layer 21 with the low refractivity has a lower refractivity than the second material layer 22 with the high refractivity. In the embodiment, a material of the first material layer 21 is silicon oxide, and a material of the second material layer 22 is titanium oxide. For example, the silicon oxide may have a refractivity of about 1.47 at 450 nm, and the titanium oxide may have a refractivity of about 2.55 at 450 nm. It should be understood that the materials of the first material layer 21 and the second material layer 22 are not limited to the silicon oxide and the titanium oxide, for example, the material of the first material layer 21 can also be fluoride, as long as the first material layer 21 and the second material layer 22 have different refractivites and are optically transparent. Other insulation layers 60 or semiconductor layers can be used as the first material layer 21 and the second material layer. In the embodiment, dielectric layers such as silicon oxide and titanium oxide are more suitable due to their high light transmittance, easy deposition and relatively large refractivity difference.

In an embodiment, in the embodiment, an optical thickness of each first material layer is λ₁/4, and λ₁>350 nm, to thereby ensure stability of the coating of the first material layer 21. An optical thickness of each second material layer is λ₂/4, and 350 nm≤λ₂≤880 nm, to thereby avoid influence of too small thickness on the stability of the second material layer 22, while also allowing the optical thickness to cover entire visible light region.

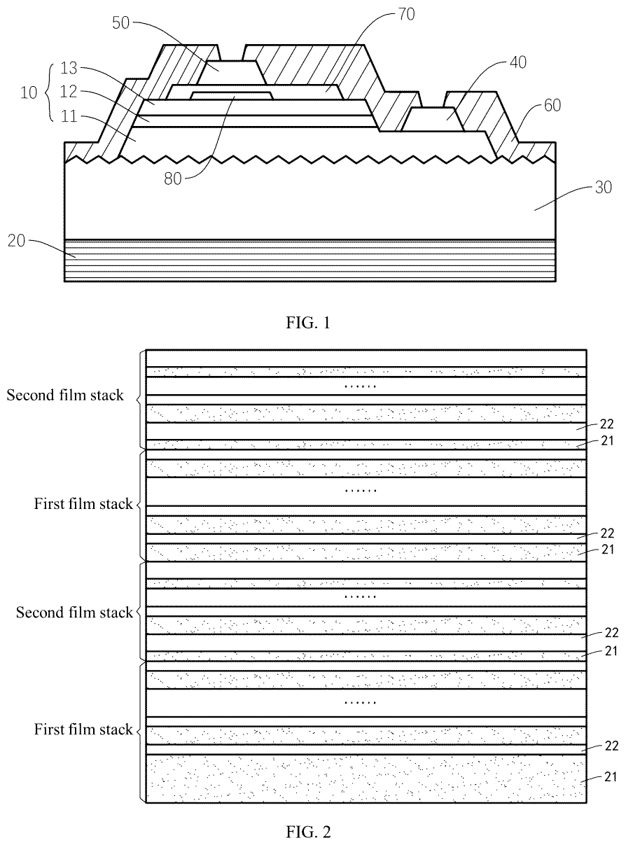

Please refer to FIG. 2, each of the first film stacks includes at least one pair layer, each pair layer consists of the first material layer 21 and the second material layer 22, and an optical thickness of the first material layer 21 is greater than that of the second material layer 22 in each pair layer. Due to a low refractivity of the first material layer 21 relative to the second material layer 22, the light absorption rate of the first material layer 21 is low relative to that of the second material layer 22. Therefore, through the design mode of the first film stacks, the light absorption rate of the entire structure of the Bragg reflector 20 is greatly reduced, and the refractivity near the Brewster angle is also increased, to thereby effectively improve an internal reflectivity of the light-emitting diode with an incident angle in the range of 50° to 60°.

Please refer to FIG. 2, each of the second film stacks includes multiple pair layers, each pair layer consists of the first material layer 21 and the second material layer 22, and each of the second film stacks is formed by repeatedly and alternately stacking a pair layer with the optical thickness of the first material layer 21 greater than that of the second material layer 22 and a pair layer with the optical thickness of the first material layer 21 smaller than that of the second material layer 22. Through the design mode of the second film stacks, the refractivity near the Brewster angle is increased, to thereby effectively improve an internal reflectivity of the light-emitting diode with an incident angle in the range of 30° to 40°.

It should be noted that the stacking method in FIG. 2 is merely one embodiment, the numbers of the first film stacks and the second film stacks, and the numbers of the first material layers 21 and the second material layers 22 can be adjusted and changed according to actual needs, and should not be limited to the numbers shown in FIG. 2.

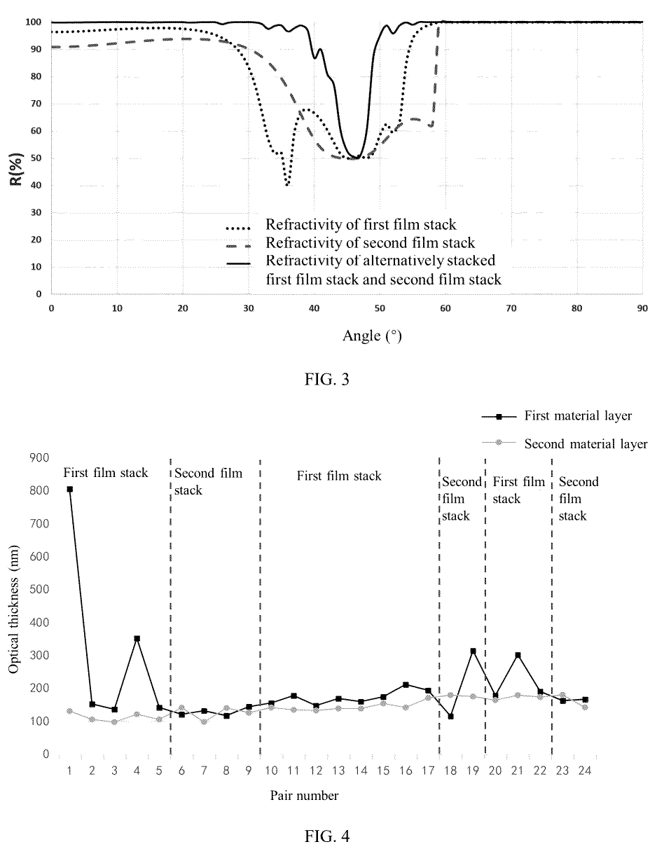

In order to verify the light-emitting effect of the light-emitting diode with the above Bragg reflector 20, please refer to FIG. 3, FIG. 3 illustrates a curve diagram of internal refractivity of chips with different stacking sequences of the Bragg reflectors 20 with angle changes, and it shows a curve comparison between the internal refractivity changes of chips of Bragg reflectors formed by only stacking the first film stacks, only stacking the second film stacks, and repeatedly and alternately stacking the first film stacks and the second film stacks. It can be seen that in the arrangement of material layers with different optical thicknesses, the structure in which the first film stacks and the second film stacks are repeatedly and alternately stacked can improve the reflection characteristics. According to FIG. 3, when the Bragg reflector is formed by stacking only the first film stacks or the second film stacks, the reflectivity of the chip is suddenly reduced about 30° to 60°. The reason is that the angle location (30° to) 60° is the Brewster angle location, and when the light is incident at this angle, the refractivity is low. Therefore, an area near this angle should be as narrow as possible, and the area is obviously narrowed by alternately stacking the first film stacks and the second film stacks. According to FIG. 3, when the incident angle is in a range of 30° to 40°, the refractivity of the chip with the Bragg reflector formed by alternately stacking the first film stacks and the second film stacks is much higher than that of the chip with the Bragg reflector formed by only stacking the first film stacks or the second film stacks, and is proximate to 100%. Therefore, using the stacking method of the Bragg reflector 20 provided by the embodiment of the disclosure can improve the refractivity near the Brewster angle, which is reflected in improving the reflectivity of the incident angles of 30° to 40° and 50° to 60°, thereby effectively improving the light-emitting efficiency of the entire light-emitting diode.

In an embodiment, in the Bragg reflector 20, a film stack closest to the epitaxial structure 10 is the first film stack, to preferentially improve an internal reflectivity of a large-angle light-emitting diode, to thereby further improve the entire light-emitting efficiency.

In an embodiment, in the same Bragg reflector 20, the number of the layers contained in the first film stacks is same or different, for example, each first film stack may have the same 10 layers, or some first film stacks may have 8 layers and some first film stacks may have 10 layers. Similarly, the number of the layers contained in the second film stacks is same or different. Specific choices can be made according to actual needs, and there are no limitations here.

In an embodiment, the total number of layers contained in the first film stacks is greater than the total number of layers contained in the second film stacks, which helps to improve the reflectivity of the wide-angle light-emitting diode. Specifically, the number of layers contained in each first film stack is greater than or equal to 2, and the number of layers contained in each second film stack is greater than or equal to 4. That is, each first film stack includes at least one first material layer 21 and one second material layer 22, and each second film stack includes at least two first material layers 21 and two second material layers 22. Specific settings of the first film stack and the second film stack can be adjusted according to actual needs, and the embodiment is not limited by this.

In optional embodiments, a sum of a number of the pair layers of the first film stacks and a number of the pair layers of the second film stacks is in a range of 15 pairs to 30 pairs. Specifically, no matter how the stacking mode of the first film stacks and the second film stacks changes, the reflectivity of the Bragg reflector 20 will increase with the increase of the number of stacked layers. Therefore, the number of the stacked pair layers should be as large as possible. The pair layers of the disclosure is between 15 pairs to 30 pairs, to thereby more effectively improve the reflectivity near the Brewster angle.

In some exemplary embodiments, a material layer closest to the epitaxial structure 10 is defined as a first layer, and the first layer is a low refractivity material. An optical thickness of the first layer is greater than that of other material layers in the Bragg reflector, which not only protects the Bragg reflector 20, but also reduces the influence of a rough bottom surface of the substrate 30 on the Bragg reflector 20 formed on the bottom surface of the substrate 30. Specifically, the first layer can be the first material layer 21 or the second material layer 22. In the embodiment, the first layer is the first material layer 21, which can be silicon oxide. Generally, due to adhesive intensity of the silicon oxide greater than that of the titanium oxide, the silicon oxide is used to be adhered on the substrate 30. Specifically, the optical thickness of the first layer is in a range of 588 nm to 1470 nm, to further enhance reflection, and improve the total reflection effect.

In addition, a material layer farthest from the epitaxial structure 10 is defined as a last layer, the last layer can be the first material layer 21 or the second material layer 22, and is not limited here.

As shown in FIG. 4, the embodiment provides a Bragg reflector 20 with 24 pair layers, each pair layer consists of the first material layer 21 and the second material layer 22. The number of the first film stacks is 3, and the number of the second film stacks is 3. Specifically, pair numbers 1-5 represent the optical thicknesses of 5 pair layers in the first one of the first film stacks, pair numbers 6-9 represent the optical thicknesses of 4 pair layers in the first one of the second film stacks, pair numbers 10-17 represent the optical thickness of 8 pair layers in the second one of the first film stacks, pair numbers 18 and 19 represent the optical thicknesses of 2 pair layers in the second one of the second film stacks, pair numbers 20-22 represent the optical thicknesses of 3 pair layers in the third one of the first film stacks, and pair numbers 23 and 24 represent the optical thicknesses of 2 pair layers in the third one of the second film stacks. In the embodiment, the number of layers contained in the first film stacks is different from the number of layers contained in the second film stacks, and the number of layers contained in the first film stacks is greater than the number of layers contained in the second film stacks.

In an embodiment, the light-emitting diode further includes a first electrode 40, a second electrode 50 and an insulation layer 60. The first electrode 40 is disposed on the first semiconductor layer 11, and electrically connected to the first semiconductor layer 11. The second electrode 50 is disposed on the second semiconductor layer 13, and electrically connected to the second semiconductor layer 13. The insulation layer 60 covers at least part of the epitaxial structure 10.

In the embodiment, the first electrode 40 and the second electrode 50 can be metal electrodes, that is, the first electrode 40 and the second electrode 50 are made of metal materials. For example, the first electrode 40 and the second electrode 50 are made of at least one selected from the group consisting of nickel, gold, chromium, titanium, platinum, palladium, rhodium, iridium, aluminum, tin, indium, tantalum, copper, cobalt, iron, ruthenium, zirconium, tungsten, and molybdenum, or at least one alloy or laminate selected from the above materials. As an example, the first electrode 40 can be an N electrode, and the second electrode 50 can be a P electrode.

In other optional embodiments, the light-emitting diode further includes a transparent conductive layer 70 and a current blocking layer 80. The transparent conductive layer 70 is disposed between the second electrode 50 and the epitaxial structure 10. The current blocking layer 80 is disposed in the transparent conductive layer 70.

The current blocking layer 80 is used to block current, to prevent the current from crowding right below the electrode and scatter the current. The transparent conductive layer 70 is used as a channel through which current flows. Through this setting, when the current flows through the transparent conductive layer 70 and the entire surface of the first semiconductor layer 11, current crowding is avoided, and the current is ensured to spread evenly on the surface of the first semiconductor layer 11, so as to improve the light-emitting efficiency.

In an embodiment, the current blocking layer 80 can be silicon oxide, silicon nitride (Si₃N₄) or their composite structure. The material of the transparent conductive layer 70 is a transparent conductive material including at least one selected from the group consisting of indium tin oxide, cadmium tin oxide, indium oxide and zinc oxide, zinc gallium oxide, indium oxide, indium doped zinc oxide, aluminum doped zinc oxide, gallium doped zinc oxide, and aluminum doped indium tin oxide. In the embodiment, the transparent conductive layer 70 is an indium tin oxide layer formed by evaporation or sputtering, such as an indium tin oxide semiconductor transparent conductive film.

The insulation layer 60 covers the epitaxial structure 10, and can also cover a part of the first electrode 40 and a part of the second electrode 50. The insulation layer 60 has different effects according to the position. For example, when the insulation layer 60 covers a side wall of the epitaxial structure 10, the insulation layer 60 can be used to prevent electrical connection between the first semiconductor layer 11 and the second semiconductor layer 13 due to leakage of conductive materials, to thereby reduce the possibility of short circuit abnormalities in the light-emitting diode. However, the embodiment is not limited to this. The material of the insulation layer 60 includes a non-conductive material. The non-conductive material is an inorganic material or a dielectric material. The inorganic material can include silica gel. The dielectric material can include an electrically insulating material, such as aluminum oxide, silicon nitride, silicon oxide, titanium oxide, or magnesium fluoride. For example, the insulation layer 60 can be silicon dioxide, silicon nitride, titanium oxide, tantalum oxide, niobium oxide, barium titanate, or a combination thereof.

An embodiment of the disclosure further provides a light-emitting device, which can use the light-emitting diode described by any one of the above embodiments, to effectively improve the photoelectric performance of the light-emitting device.

What is claimed is:

1. A light-emitting diode, comprising:
a substrate, defining a first surface and a second surface that are oppositely disposed;
an epitaxial structure, disposed on the first surface, and comprising an active layer; and
a Bragg reflector, disposed on the second surface;
wherein the Bragg reflector comprises first film stacks and second film stacks that are repeatedly and alternately stacked, each of the first film stacks and the second film stacks comprises a first material layer with a first refractivity and a second material layer with a second refractivity, the first material layer and the second material layer are repeatedly and alternately stacked, and the first refractivity is lower than the second refractivity;
wherein each of the first film stacks comprises at least one pair layer, each pair layer consists of the first material layer and the second material layer, and an optical thickness of the first material layer is greater than that of the second material layer in each pair layer; and
wherein each of the second film stacks comprises a plurality of pair layers, each of the plurality of pair layers consists of the first material layer and the second material layer, and each of the second film stacks is formed by repeatedly and alternately stacking one of the plurality of pair layers with an optical thickness of the first material layer greater than that of the second material layer and one of the plurality of pair layers with an optical thickness of the first material layer smaller than that of the second material layer.

2. The light-emitting diode as claimed in claim 1, wherein in the Bragg reflector, the first film stacks respectively have same or different numbers of layers, and the second film stacks respectively have same or different numbers of layers.

3. The light-emitting diode as claimed in claim 1, wherein in the Bragg reflector, a total number of layers of the first film stacks is greater than a total number of layers of the second film stacks.

4. The light-emitting diode as claimed in claim 1, wherein a number of layers of each of the first film stacks is greater than or equal to 2, and a number of layers of each of the second film stacks is greater than or equal to 4.

5. The light-emitting diode as claimed in claim 1, wherein in the Bragg reflector, a number of the first film stacks and a number of the second film stacks are same or different.

6. The light-emitting diode as claimed in claim 1, wherein in the Bragg reflector, a film stack closest to the epitaxial structure is one of the first film stacks.

7. The light-emitting diode as claimed in claim 1, wherein a material of the first material layer is silicon oxide, and a material of the second material layer is titanium oxide.

8. The light-emitting diode as claimed in claim 1, wherein in the Bragg reflector, a sum of a number of the pair layers of the first film stacks and a number of the pair layers of the second film stacks is in a range of 15 pairs to 30 pairs.

9. The light-emitting diode as claimed in claim 1, wherein in the Bragg reflector, a material layer closest to the epitaxial structure is defined as a first layer, the first layer is made of a low refractivity material, and an optical thickness of the first layer is greater than that of other material layers in the Bragg reflector.

10. The light-emitting diode as claimed in claim 9, wherein the first layer is the first material layer.

11. The light-emitting diode as claimed in claim 9, wherein the optical thickness of the first layer is in a range of 588 nm to 1470 nm.

12. The light-emitting diode as claimed in claim 1, wherein the optical thickness of each first material layer is λ₁/4, and λ₁>350 nm.

13. The light-emitting diode as claimed in claim 1, wherein the optical thickness of each second material layer is λ₂/4, and 350 nm≤/λ₂≤880 nm.

14. The light-emitting diode as claimed in claim 1, wherein a thickness of the Bragg reflector is in a range of 3 μm to 6 μm.

15. The light-emitting diode as claimed in claim 1, wherein a light-emitting wavelength of the light-emitting diode is in a range of 420 nm to 480 nm.

16. The light-emitting diode as claimed in claim 1, wherein the substrate is a transparent substrate.

17. The light-emitting diode as claimed in claim 16, wherein the epitaxial structure further comprises a first semiconductor layer and a second semiconductor layer stacked on two sides of the active layer, respectively; and the first semiconductor layer is located proximate to the transparent substrate.

18. The light-emitting diode as claimed in claim 17, further comprising:
a first electrode, disposed on the first semiconductor layer, and electrically connected to the first semiconductor layer;
a second electrode, disposed on the second semiconductor layer, and electrically connected to the second semiconductor layer; and
an insulation layer, covering at least part of the epitaxial structure.

19. The light-emitting diode as claimed in claim 18, further comprising:
a transparent conductive layer, disposed between the second electrode and the epitaxial structure; and
a current blocking layer, disposed in the transparent conductive layer.

20. A light-emitting device, comprising the light-emitting diode as claimed in claim 1.
